(19) United States
(12) Patent Application Publication
(10) Pub. No.: US 2002/0000547 A1
(43) Pub. Date: Jan. 3, 2002

(54) Silicon/graphite composite ring for supporting silicon wafer, and dry etching apparatus equipped with the same

(75) Inventor: Akira Yamaguchi, Kawagoe-shi (JP)

Correspondence Address: ARMSTRONG,WESTERMAN, HATTORI,, MCLELAND & NAUGHTON, LLP, 1725 K STREET, NW, SUITE 1000, WASHINGTON, DC, 20006, US

(73) Assignee: Nisshinbo Industries, Inc.,, Tokyo (JP)

(21) Appl. No.: 09/863,355

(22) Filed: May 24, 2001

(30) Foreign Application Priority Data
May 26, 2000 (JP) 2000-156064

(51) Int. Cl. H01L 47/00

(52) U.S. Cl. 257/4

(57) ABSTRACT

A composite ring member of the present invention for supporting a silicon wafer, which is structured in such a way to have a first cylindrical ring of silicon having a receiving section by which a silicon wafer is supported and second cylindrical ring of graphite, wherein the second cylindrical ring is joined to the back side of the first ring by metal brazing or a thermoconductive adhesive. The composite ring member of the present invention for supporting a silicon wafer has the effect of widening etching treatment range to increase semiconductor device yield and reduce the production cost, while preventing contamination with an impurity and keeping good wafer positional stability.

### BACKGROUND OF THE INVENTION

This invention relates to a silicon/graphite composite ring for supporting a silicon wafer used for semiconductor devices, and a dry etching apparatus equipped with the same ring, more particularly to the silicon/graphite composite ring for supporting a silicon wafer used for semiconductor devices which can widen etching treatment range to increase semiconductor device yield while preventing contamination with an impurity and keeping good wafer positional stability, and the dry etching apparatus equipped with the same ring.

As information-related devices centered by computers develop, semiconductor integrated circuits as the major constituents for these devices are increasingly demanded to have a higher degree of integration. These circuits have been produced in a clean atmosphere, such as that in a clean room, to secure necessary performance, because they are extremely sensitive to contamination by an impurity. The stock materials for these devices must be also kept away from the impurity. It is also necessary, needless to say, to control evolution of an impurity from the members that constitute the production facilities.

The wafer is treated in a reaction chamber which can be evacuated to a high degree of vacuum for the processes, represented by ion-implantation, dry etching and sputtering. Increased degree of integration of the semiconductor integrated circuit increases the purity level standards, which, in turn, requires the materials for the chamber and its members to have characteristics of being less contaminated with an impurity.

FIG. 3 illustrates the members within the chamber, taking dry etching as the example. The chamber generally includes a pair of electrodes, upper and lower electrodes facing each other, the lower electrode being connected to a high-frequency power source to generate a plasma in the space between the electrodes. A silicon wafer is placed right above the lower electrode via a supporting member, and is etched with an etchant in the plasma atmosphere.

The wafer-supporting member in a dry etching device has been a single cylindrical ring with a receiving section by which a silicon wafer is supported. More recently, the single cylindrical ring is replaced, although on an experimental basis, a composite ring with a cylindrical ring of silicon reinforced with a supported cylindrical ring of metal, e.g., aluminum, because of extraordinary fragility of the single cylindrical ring.

However, the composite ring of silicon and metal (e.g., aluminum) involves various disadvantages, e.g., possible contamination with an impurity generated from the metal; insufficient cooling efficiency of the composite ring itself, which limits etching treatment speed; and large difference between silicon and the metal in thermal expansion coefficient, which produces a thermal strain to deteriorate positional stability of the silicon wafer and make it difficult to secure uniform etching treatment density. These disadvantages lead to decreased semiconductor device (i.e., silicon wafer) yield in the dry etching process.

Various wafer-treating apparatus members have been proposed to solve the above problems for the semiconductor production systems. For example, Japanese Patent Laid-Open No.10-256177 discloses a wafer-treating apparatus member which incorporates glass like carbon of specific thickness attached to the metal or graphite member surface irradiated with ion beams or the like.

However, these efforts have failed to realize the members for silicon wafer supporting apparatuses free of the above problems. In other words, there is no such a member which is free of contamination with an impurity, high in cooling efficiency and hence free of the problems resulting from thermal strains, and giving a high silicon wafer yield. Therefore, development of the advanced wafer-supporting members has been strongly demanded for wafer-supporting apparatuses to increase semiconductor device yield.

It is an object of the present invention to provide a composite ring for supporting a silicon wafer, free of the problems associated with the conventional composite ring of silicon and a metal (e.g., aluminum), i.e., free of contamination with an impurity, high in cooling efficiency and hence free of the problems resulting from thermal strains, and giving a high silicon wafer yield. It is another object of the present invention to provide a dry etching apparatus equipped with the same.

### SUMMARY OF THE INVENTION

The inventors of the present invention have found, after having extensively studied to develop the optimum silicon wafer supporting member free of the above problems, that the composite ring member and dry etching apparatus equipped with the same can widen etching treatment range to increase semiconductor device yield while preventing contamination with an impurity and keeping good wafer positional stability, when the member is structured in such a way to have a first cylindrical ring of silicon having a receiving section by which a silicon wafer is supported and second cylindrical ring of graphite joined to the back side of the first ring, reaching the present invention.

The first invention of the present invention provides a composite ring member for supporting a silicon wafer, which is structured in such a way to have a first cylindrical ring of silicon having a receiving section by which a silicon wafer is supported and second cylindrical ring of graphite, wherein the second cylindrical ring is joined to the back side of the first ring by metal brazing or a thermoconductive adhesive.

The second invention of the present invention provides the composite ring member for supporting a silicon wafer of the first invention, wherein the second cylindrical ring is coated with glass like carbon at least on the surface opposite to the first ring.

The third invention of the present invention provides a dry etching apparatus equipped with the composite ring member for supporting a silicon wafer of the first or second invention.

### BRIEF DESCRIPTION OF THE DRAWINGS

FIG. 1 schematically illustrate the member for supporting a wafer;

FIG. 2 presents the oblique view of the member for supporting a wafer; and

FIG. 3 schematically illustrate the dry etching apparatus.

Reference Numerals

| | | |
|---|---|---|
| 1: Etchant gas inlet | 2: Discharge nozzle; | 3: Upper electrode |
| nozzle; | | |
| 4: Lower electrode | 5: Silicon wafer; | 6: Plasma; |
| 7: Power source for rf | 8: Silicon ring; | 9: Graphite ring; |
| waves; | | |
| 10: Cover; | 11: Joint phase. | |

### DESCRIPTION OF THE PREFERRED EMBODIMENTS

As described above, this invention relates to the silicon/graphite composite ring for supporting a silicon wafer used for semiconductor devices which can widen etching treatment range to increase semiconductor device yield while preventing contamination with an impurity and keeping good wafer positional stability, and the dry etching apparatus equipped with the same ring. The preferred embodiments include the followings.

(1) The composite ring member for supporting a silicon wafer of the first invention, wherein the first and second cylindrical rings are joined to each other by metal brazing.

(2) The composite ring member for supporting a silicon wafer of the first invention, wherein the brazing metal is indium.

(3) The composite ring member for supporting a silicon wafer of the first invention, wherein the first and second cylindrical rings are joined to each other by a themoconductive adhesive.

(4) The composite ring member for supporting a silicon wafer of (3) above, wherein the themoconductive adhesive is of an epoxy resin incorporated with at least one type of filler selected from the group consisting of carbon, silver, aluminum and nickel.

(5) The composite ring member for supporting a silicon wafer of the second invention, wherein the glass like carbon coating layer is at least 2 to 3 μm thick.

The present invention is described in more detail.

1. First Cylindrical Ring

A silicon-graphite composite ring is used for the ring member of the present invention for supporting a silicon wafer, wherein the first cylindrical ring as the clamp ring by which a silicon wafer is directly supported is made of silicon (the ring may be hereinafter referred to as the silicon ring). In particular, the silicon ring is used to fix the silicon wafer during the etching step, protect the outer periphery of the wafer and prevent contamination of the wafer, thereby widening the etching treatment range for the wafer.

For the first cylindrical ring of silicon to work as the clamp ring for a silicon wafer, it should have a receiving section on the surface, by which the wafer is supported. The wafer-receiving section is not limited, so long as it can stably fix the silicon wafer during the etching step. It generally has a shape of cylindrical step, made as high as the silicon wafer to widen its etching treatment range.

Silicon as the basis of the silicon ring is not limited, but the high-purity, high-density one is preferable to widen the silicon wafer etching treatment range and totally utilize the effective device region. One of the desirable silicon types is the P-type single crystal silicon doped with boron (B) and having the crystal orientation of [100]. Its electroresistivity is preferably similar to that of the silicon wafer, and generally in a range of 1 to 20 Ω·cm.

2. Second Cylindrical Ring

The composite ring of the present invention for supporting a silicon wafer also includes the second cylindrical ring of graphite working as the cooling ring (the ring may be hereinafter referred to as the graphite ring), which is joined to the back side of the first cylindrical ring (i.e., silicon ring) by which the silicon wafer is directly supported. In particular, the graphite ring is used to prevent contamination of the silicon wafer with an impurity during the etching step and keep good positional stability of the silicon wafer.

The graphite ring, serving as the cooling ring, should be highly thermoconductive (i.e., having a high thermal conductivity) and has such a thermal expansion coefficient as to keep sufficiently small difference in the coefficient between itself and the silicon ring serving as the clamp ring. The composite ring with a graphite ring having a low thermal conductivity and thermal expansion coefficient sufficiently different from that of the silicon ring cannot well cope with the requirements, such as increasing size of silicon wafer, increasing treatment temperature, and treatment in which temperature is rapidly increased or decreased, causing various problems, such as uneven heating of the silicon wafer, and cracking resulting from thermal strain and stress. The conventional ring of an aluminum compound (e.g., alumina and alumite) has a low thermal conductivity and thermal expansion coefficient sufficiently different from that of silicon, and use of such a ring may cause problems, e.g., evolution of thermal strains. Therefore, the present invention, using a graphite ring as the cooling ring, brings about significant effects.

Graphite as the basis of the graphite ring is not limited, but the high-purity one is preferable to cause no contamination with an impurity during the etching step, and has a high thermal conductivity and such a thermal expansion coefficient as to keep sufficiently small difference in the coefficient between itself and the silicon ring. One of the examples of such graphite types is a semiconductor-grade one, e.g., LE-CARBONE's CX-2123, CX-2114 or CX-2206, or TOYO TANSO's EGF-262 or EGF-264 as the commercial one.

The graphite ring may be a composite of graphite and glass like carbon.

The graphite ring is preferably coated with glass like carbon, at least on the surface opposite to the first cylindrical ring, where it is exposed to the etchant gas during the etching step.

It is coated with glass like carbon to a thickness normally in a range from 2 to 3μm. The coating method is not limited, and can be adequately selected from the ones normally followed.

Some of the examples of the coating methods are (A) immersing a formed graphite article in a resin solution to impregnate it with the resin to the graphite particles inside, and firing it to coat these particles with glass like carbon, (B) spraying a resin solution over a formed graphite article to form the resin surface layer thereon, and firing it to coat the article surface with glass like carbon, and (C) combination of (A) and (B), i.e., immersing a formed graphite article in a resin solution to impregnate it with the resin and firing it, and then forming the resin surface layer thereon and firing it again.

The resins useful for these methods include thermosetting resins, e.g., polycarbodiimide and phenolic resins.

A formed graphite article may be impregnated with a resin under an atmospheric pressure, or under a vacuum adequately set to adjust impregnation depth of the resin.

The methods (B) and (C) are more preferable for the present invention, because they can fill the pores in the vicinity of the graphite surface more extensively to increase surface hardness.

The glass like carbon layer also serves as the protective layer for the graphite ring, controls evolution of dust from the graphite ring, and contributes to improved corrosion resistance or the like. In particular, it controls evolution of gases from the graphite ring in a plasma atmosphere during the etching step, and also prevents the various problems, e.g., separation of the layer which forms the oxide layer on the graphite ring and contamination of the wafer with the resultant particles.

The glass like carbon is referred to as non-graphitizable carbon or hard carbon. It is not limited, and any stock material or production method may be used, so long as it is formed by solid-phase carbonization of an organic material. The stock materials may be a thermosetting resin (e.g., cellulose or furfuryl alcohol resin) or thermoplastic resin), and the method may be selected from the ones proposed for specific stock materials.

3. Silicon-graphite Composite Ring

The silicon-graphite composite ring of the present invention comprises the silicon ring as the first cylindrical ring and graphite ring as the second cylindrical ring for cooling, which may be joined to the back side of the first ring.

For the graphite ring as the second cylindrical ring to serve as the cooling ring, it is preferably joined to the silicon ring by brazing with a thermoconductive metal or a thermoconductive adhesive efficiently radiating heat, the former being more preferable.

The brazing metals useful for the present invention include thermoconductive metals, e.g., silver, copper, aluminum, alumina (aluminum oxide), indium, beryllium oxide, nickel, titanium, zirconium and alloys thereof, of which indium is more preferable for its low melting point.

The thermoconductive adhesives useful for the present invention are generally of an epoxy resin incorporated with a filler, e.g., carbon, silver, aluminum or nickel, to make the base material around 10 times more thermoconductive. An elastomer, e.g., silicone, polyurethane or polysulfide, may be used as the matrix for the adhesive, as required, when it is required to be soft or elastic.

The composite structure with the first cylindrical ring of silicon and the second cylindrical ring of graphite joined to the back side of the first cylindrical ring can widen etching treatment range to increase semiconductor device yield while preventing contamination with an impurity and keeping good wafer positional stability.

When used in a high-density plasma atmosphere, in particular, the composite ring can rapidly release heat to heat-transmitting members, to improve uniformity of temperature of the silicon ring as the member for supporting a silicon wafer and, hence, positional stability of the silicon wafer. As a result, it can widen etching treatment range to increase silicon wafer yield.

### EXAMPLE

The present invention is described in more detail using examples and referring to the attached drawings, which by no means limit the present invention.

### Example 1

Outline of the Composite Ring Member for Supporting a Silicon Wafer

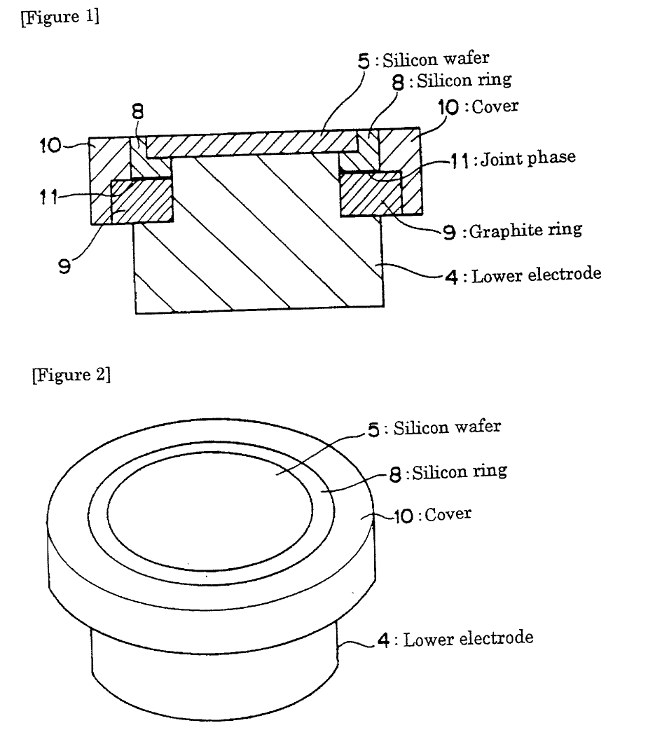

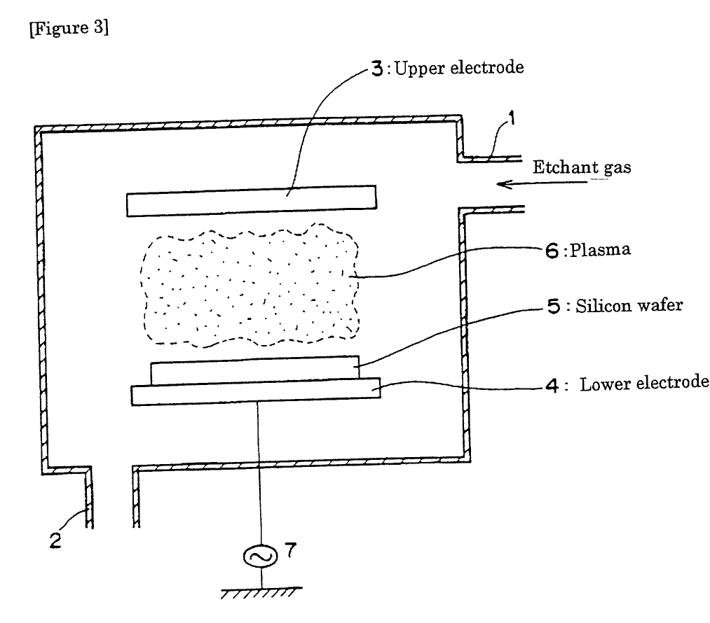

The composite ring member of the present invention for supporting a silicon wafer supports the wafer in a dry etching apparatus in which the silicon wafer is treated. FIGS. 1 and 2 outline the composite ring member for supporting a silicon wafer, and FIG. 3 the dry etching apparatus.

Referring to FIGS. 1 and 2, the silicon ring 8 has dimensions of outer diameter: 220 mm, inner diameter: 196 mm and thickness: 4 mm; the step for supporting the silicon wafer 5 has dimensions of diameter: 202 mm and thickness: 1 mm; and the graphite ring 9 has dimensions of outer diameter: 270 mm, inner diameter: 196 mm and thickness: 8.3 mm.

The silicon ring 8 was joined to the graphite ring 9 by metal brazing via the joint phase 11, to form the composite ring, where the joint phase was of indium as the brazing metal which melts under heating at around 160° C.

The composite ring was covered by the cover 10 of quartz, which hides the graphite ring 9 in FIG. 2 which presents the oblique view of the member for supporting the wafer.

The composite ring thus prepared was used in a dry etching apparatus for silicone wafers as the member for supporting the wafer.

### Comparative Examples 1 and 2

COMPARATIVE EXAMPLE 1 prepared the composite ring in the same manner as in EXAMPLE 1, except that the graphite ring 9 was replaced by an alumite ring which has been normally used, and used it in a dry etching apparatus for silicone wafers as the member for supporting the wafer in the same manner as in EXAMPLE 1.

COMPARATIVE EXAMPLE 2 prepared the composite ring in the same manner as in EXAMPLE 1, except that the graphite ring 9 was replaced by an alumite ring which has been normally used and the joint phase 11 prepared by metal brazing with indium as the brazing metal was replaced by that of a silicone-based adhesive, and used it in a dry etching apparatus for silicone wafers as the member for supporting the wafer in the same manner as in EXAMPLE 1.

The silicon wafer was found to show better positional stability in EXAMPLE 1 than in COMPARATIVE EXAMPLES 1 and 2.

These results are discussed. First, compare the composite ring prepared by EXAMPLE 1 with those prepared by COMPARATIVE EXAMPLES 1 and 2 in thermal expansion. It is considered that service temperature of the member for supporting a silicon wafer increases from room temperature to 80° C., and eventually to around 100° C. during the etching step in a dry etching apparatus for silicon wafers. The composite ring thermally expands and increases in volume during the etching step, to adversely affect positional stability of the silicon wafer. For example, it is estimated that the silicon ring expanded by 8 μm in the radial direction, and the graphite ring by 10 μm at the portion having an outer diameter corresponding to that of the silicon ring (i.e., at the portion in contact with the silicon ring via the joint phase). On the other hand, the alumite ring thermally expanded by 45 μm at the portion having an outer diameter corresponding to that of the silicon ring (i.e., at the joint). As a result, the composite ring prepared by EXAMPLE 1 suffered much smaller thermal strain at the joint, resulting from the much smaller difference between the rings in thermal expansion, and hence showed better positional stability of the silicon wafer than those prepared by COMPARATIVE EXAMPLES 1 and 2.

Moreover, the composite ring prepared by EXAMPLE 1 used the brazing metal at the joint between the silicon and graphite rings, which was thermoconductive and hence having higher cooling efficiency, thus improving uniformity of temperature of the silicon ring as the member for supporting a silicon wafer and widening etching treatment range.

It was also found that the composite ring prepared by COMPARATIVE EXAMPLE 1, comprising the silicon and alumite rings joined by indium as the brazing metal, showed failures, e.g., damage at the joint, when subjected to repeated etching steps, because of the strong joint layer of indium as the brazing metal.

These results indicate that the silicon-graphite composite ring for supporting a silicon wafer improves etching uniformity of the silicon wafer and secures its positional stability in a dry etching apparatus, when it comprises the silicon ring for supporting the silicon wafer and graphite ring as the cooling ring joined to the silicon ring via a brazing metal.

The composite ring member of the present invention for supporting a silicon wafer has the effect of widening etching treatment range to increase semiconductor device yield and reduce the production cost, while preventing contamination with an impurity and keeping good wafer positional stability.

We claim:

1. A composite ring member for supporting a silicon wafer, which is structured in such a way to have a first cylindrical ring of silicon having a receiving section by which a silicon wafer is supported and second cylindrical ring of graphite, wherein said second cylindrical ring is joined to the back side of said first ring by metal brazing or a thermoconductive adhesive.

2. The composite ring member for supporting a silicon wafer according to claim 1, wherein said second cylindrical ring is coated with glass like carbon at least on the surface opposite to the first ring.

3. A dry etching apparatus equipped with said composite ring member for supporting a silicon wafer according to claim 1.

4. A dry etching apparatus equipped with said composite ring member for supporting a silicon wafer according to claim 2.
